(19) United States
(12) Patent Application Publication
(10) Pub. No.: US 2017/0261663 A1
(43) Pub. Date: Sep. 14, 2017

(54) ATTENUATION DEVICE FOR BLUE LIGHT AND MANUFACTURING METHOD THEREOF, SUBSTRATE, DISPLAY DEVICE, AND SMART WEARABLE APPARATUS

(71) Applicant: BOE TECHNOLOGY GROUP CO., LTD., Beijing (CN)

(72) Inventor: Yingyi LI, Beijing (CN)

(73) Assignee: BOE Technology Group Co., Ltd., Beijing (CN)

(21) Appl. No.: 15/528,648

(22) PCT Filed: Feb. 26, 2016
(86) PCT No.: PCT/CN2016/074708

§ 371 Date: May 22, 2017

(30) Foreign Application Priority Data
Sep. 17, 2015 (CN) 201510596020.4

(51) Int. Cl. G02B 5/28; C23C 16/44; G02F 1/1368; F21V 8/00; G02F 1/1362

(52) U.S. Cl. CPC G02B 5/285; G02B 6/0011; G02F 1/136209; G02F 1/1368; C23C 16/44; G02F 2001/136222

(57) ABSTRACT

An attenuation device for blue light includes a base and a blue light attenuating film system, the blue light attenuating film system including a film layer of first refractive index and a film layer of second refractive index alternately disposed on the same side of the base, a total number of the film layer of first refractive index and the film layer of second refractive index being 5 at least; wherein a film layer closest to the base and a film layer farthest from the base in the blue light attenuating film system are both the film layer of first refractive index, and the film layer of first refractive index has a refractive index greater than that of the film layer of second refractive index. A display device and a wearable product, as well as a preparation method of the attenuation device for blue light are further provided.

### TECHNICAL FIELD

Embodiments of the present disclosure relate to a blue light attenuation device for blue light and a manufacturing method thereof, a substrate, a display device, and a smart wearable apparatus.

### BACKGROUND

At present, light emitted from display devices in the market is generally in a wavelength band of 380-780 nm. The light having a wavelength band of 380-500 nm is known as blue light. The blue light is visible light with high energy. It can directly penetrate the cornea and lens, irradiates on the fundus macular area which causes accelerated oxidation of the macular cell and does photochemical damage to the retina. Influence of blue light on children's retina is more serious. At the Annual Meeting of the Association for Research in Vision and Ophthalmology (ARVO) in 2010, ophthalmologists published that long-term reading in blue light will lead to myopia, computer syndrome, cataract and even lead to blindness. Thus, blue light is proven to be the most harmful visible light.

Blue light is widely found in artificial light sources, such as in backlight modules of liquid crystal display devices. Compared with other light sources, an LED chip used in the backlight module emits more blue light. In addition, in order to improve outdoor visibility of a display device, a backlight module with high brightness is often used as the backlight module.

Thus, how to reduce the damage of the blue light in a display device is an urgent problem to be solved.

### SUMMARY

At least one embodiment of the present disclosure provides an attenuation device for blue light, a preparation method thereof, a substrate, a display device, and a smart wearable product, in which damage of blue light can be mitigated.

At least one embodiment of the present disclosure provides an attenuation device for blue light applicable to a display device, comprising a base and a blue light attenuating film system, the blue light attenuating film system comprising a film layer of first refractive index and a film layer of second refractive index alternately disposed on the same side of the base, a total number of the film layer of first refractive index and the film layer of second refractive index being 5 at least; wherein a film layer closest to the base and a film layer farthest from the base in the blue light attenuating film system are both the film layer of first refractive index, and the film layer of first refractive index has a refractive index greater than that of the film layer of second refractive index.

In one embodiment of the present disclosure, each of the film layer of first refractive index and the film layer of second refractive index has a thickness in a range of 70-150 nm.

In one embodiment of the present disclosure, the total number of the film layer of first refractive index and the film layer of second refractive index is 21 at most.

In one embodiment of the present disclosure, the film layer of first refractive index is made of at least one of silicon nitride, titanium dioxide and zirconium dioxide; and the film layer of second refractive index is made of at least one of silicon dioxide, magnesium fluoride, hafnium oxide and alumina

At least one embodiment of the present disclosure provides a substrate applicable to a display device, comprising the attenuation device for blue light as described above, the attenuation device for blue light configured to attenuate intensity of blue light incident therein.

In one embodiment of the present disclosure, the substrate further comprises a display element; the display element and the blue light attenuation film system are provided on the same side of the base; or the display element and the blue light attenuation film system are provided on opposite sides of the base, respectively.

In one embodiment of the present disclosure, the display element comprises a thin film transistor and a pixel electrode electrically connected with a drain of the thin film transistor.

In one embodiment of the present disclosure, the display element comprises a color film layer and a black matrix.

In one embodiment of the present disclosure, the display element comprises an anode, an organic material functional layer and a cathode, wherein the blue light attenuating film system is provided on a light emitting side of the display element.

At least one embodiment of the present disclosure provides a display device, comprising the substrate as described above.

At least one embodiment of the present disclosure provides a display device, comprising a liquid crystal display panel and a backlight source, wherein the backlight source comprises the attenuation device for blue light as described above, and wherein the base of the attenuation device for blue light is a light guide plate or an optical film.

At least one embodiment of the present disclosure provides a smart wearable product comprising the display device as described above.

At least one embodiment of the present disclosure provides a preparation method of the attenuation device for blue light, comprising evaporating by evaporation method or depositing by chemical vapor deposition method the film layer of first refractive index and the film layer of second refractive index sequentially on the same side of the base, a total number of the film layer of first refractive index and the film layer of second refractive index is 5 at least, wherein a film layer closest to the base and a film layer farthest from the base are both the film layer of first refractive index, and the film layer of first refractive index has a refractive index greater than that of the film layer of second refractive index.

In the attenuation device for blue light, a preparation method thereof, a substrate, a display device, and a smart wearable product according to the embodiments of the present disclosure, by alternately providing a film layer of first refractive index and a film layer of second refractive index on the base, according to the principle of constructive interference and offset interference, the incident angle of the light in the blue light wavelength band can be made equal to the reflection angle, thereby reducing intensity of the blue light passing through the attenuation device for blue light. When applied to a display device, damage to eyes caused by the blue light from the display device can be reduced.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative structural view of a attenuation device for blue light according to one embodiment of the present disclosure;

FIG. 2 is an illustrative structural view of a attenuation device for blue light according to another embodiment of the present disclosure;

FIG. 3 is an illustrative structural view of a attenuation device for blue light according to yet another embodiment of the present disclosure;

FIG. 4 is an operational principle diagram of a attenuation device for blue light according to one embodiment of the present disclosure;

FIG. 5 is a schematic spectrogram of a liquid crystal display device in the conventional art;

FIG. 6 is a transmittance graph of a attenuation device for blue light according to one embodiment of the present disclosure;

FIG. 7 is a schematic spectrogram obtained by attenuating the blue light in FIG. 4 by use of the attenuation device for blue light having the transmittance graph as illustrated in FIG. 5;

FIG. 8a is an illustrative structural view of an array substrate for LCD comprising a attenuation device for blue light according to one embodiment of the present disclosure;

FIG. 8b is an illustrative structural view of an array substrate for LCD comprising a attenuation device for blue light according to another embodiment of the present disclosure;

FIG. 8c is an illustrative structural view of an array substrate for LCD comprising a attenuation device for blue light according to yet another embodiment of the present disclosure;

FIG. 9a is an illustrative structural view of a color filter substrate for LCD comprising a attenuation device for blue light according to one embodiment of the present disclosure;

FIG. 9b is an illustrative structural view of a color filter substrate for LCD comprising a attenuation device for blue light according to another embodiment of the present disclosure;

FIG. 9c is an illustrative structural view of a color filter substrate for LCD comprising a attenuation device for blue light according to yet another embodiment of the present disclosure;

FIG. 10a is a first illustrative structural view of an array substrate for OLED comprising a attenuation device for blue light according to one embodiment of the present disclosure;

FIG. 10b is a first illustrative structural view of an array substrate for OLED comprising a attenuation device for blue light according to another embodiment of the present disclosure;

FIG. 10c is a first illustrative structural view of an array substrate for OLED comprising a attenuation device for blue light according to yet another embodiment of the present disclosure;

FIG. 11a is a second illustrative structural view of an array substrate for OLED comprising a attenuation device for blue light according to one embodiment of the present disclosure;

FIG. 11b is a second illustrative structural view of an array substrate for OLED comprising a attenuation device for blue light according to another embodiment of the present disclosure;

FIG. 11c is a second illustrative structural view of an array substrate for OLED comprising a attenuation device for blue light according to yet another embodiment of the present disclosure; and

FIG. 12 is an illustrative structural view of a display device according to one embodiment of the present disclosure.

### DESCRIPTION OF REFERENCE NUMERALS

10—attenuation device for blue light; 101—base; 102—film layer of first refractive index; 103—film layer of second refractive index; 20—display element; 201—thin film transistor; 202—pixel electrode; 203—common electrode; 204—black matrix; 205—anode; 206—organic material functional layer; 207—cathode; 208—pixel definition layer; 30—liquid crystal display panel; 40—backlight module; 401—light guide plate; 402—optical film; R—red photoresist; G—green photoresist; B—blue photoresist.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise defined, technical terms or scientific terms used herein should be of general meaning understood by those skilled in the art. The “first”, “second” and similar wordings used in the description and the claims of the present disclosure do not indicate order, quantity or importance, but are merely intended to distinguish different components.

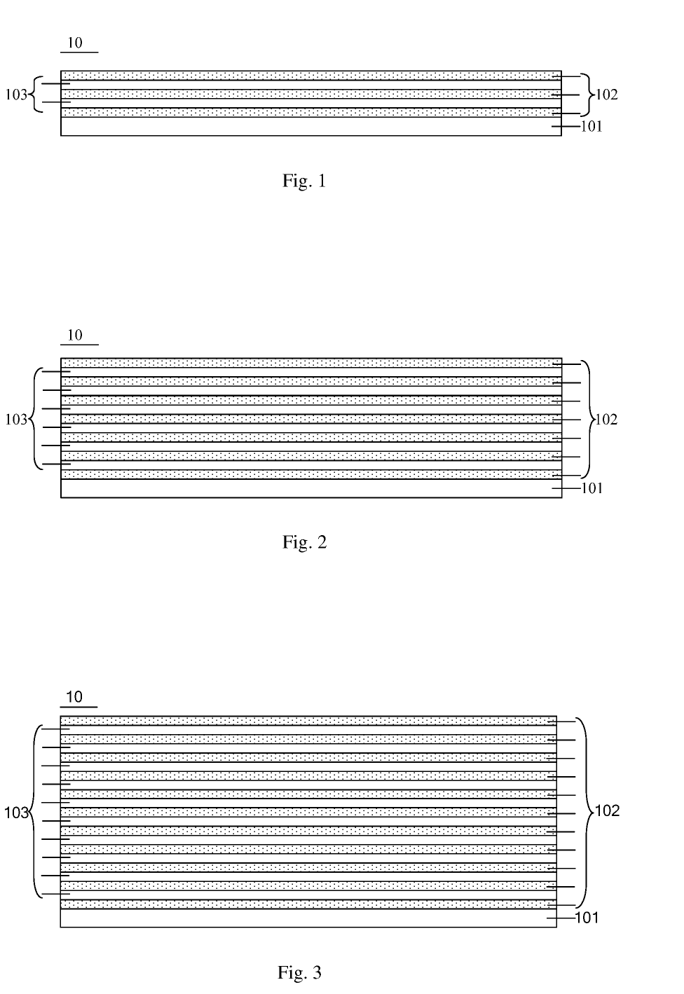

At least one embodiment of the present disclosure provides an attenuation device for blue light 10 for a display device. As illustrated in FIG. 1 to FIG. 3, the attenuation device for blue light 10 comprises a base 101 and an attenuation film system for blue light, which comprises a film layer of first refractive index 102 and a film layer of second refractive index 103 alternately disposed on the same side of the base. A total number of the film layer of first refractive index 102 and the film layer of second refractive index 103 is equal to or more than 5. The film layer of first refractive index 102 has a refractive index greater than that of the film layer of second refractive index 103. The film layer closest to the base and the film layer farthest from the base are both the film layer of first refractive index 102.

The attenuation principle for blue light of the attenuation device for blue light 10 according to the embodiments of the present disclosure is that, according to the principle of constructive interference and offset interference, by use of a multi-layer film system in which the film layer of first refractive index 102 having a high refractive index and the film layer of second refractive index 103 having a low refractive index are alternately formed, an incident angle of the light in a specific wavelength band (which is the blue light wavelength band in the embodiments of the present disclosure) is made equal to a reflection angle so that the reflection of the light in the specific wavelength band is enhanced and the transmission thereof is reduced.

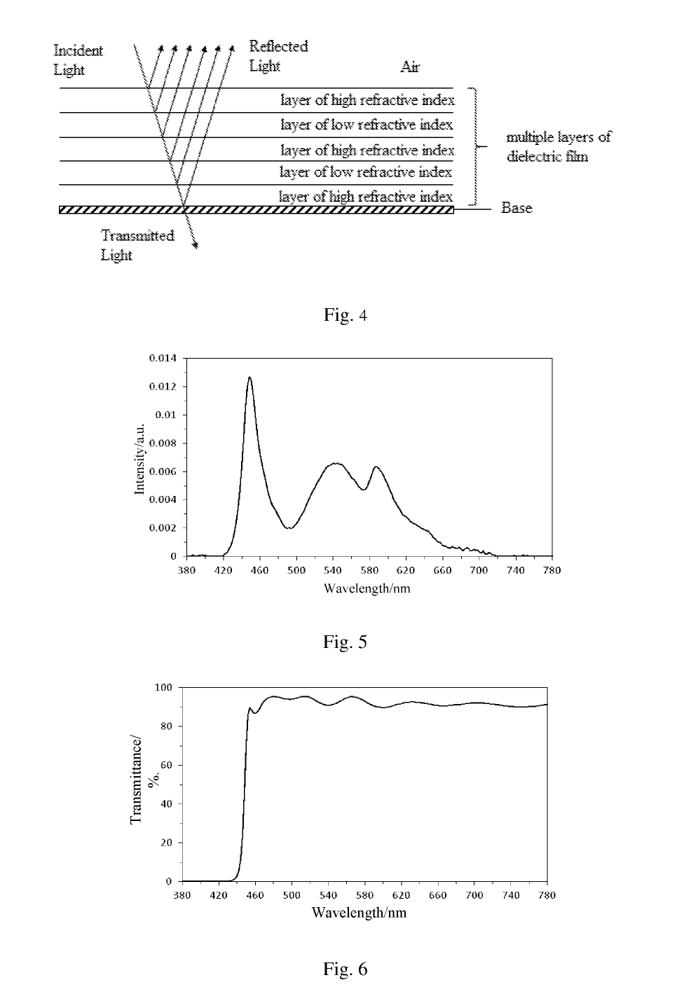

FIG. 4 is a operational principle diagram of the attenuation device for blue light according to the embodiments of the present disclosure. The attenuation device for blue light according to the embodiments of the present disclosure comprises a film layer of high refractive index and a film layer of low refractive index alternately disposed on the same side of the base. The film layer closest to the base and the film layer farthest from the base are both the film layer of high refractive index. When light is incident on the film layer of high refractive index, the reflected light has no phase shift. When light is incident on the film layer of low refractive index, the reflected light has a 180° phase shift plus a ¼ wavelength (90°) phase shift by the layer, so that the light reflected by the layer of low refractive index has a phase shift of 360°. The light reflected by the layer of low refractive index is superimposed on the light reflected by the layer of high refractive index, and the reflected light by the respective layers is superimposed in the vicinity of the center wavelength. Thus, the reflection of the light in the specific wavelength band is enhanced, while the transmission thereof is reduced.

It is to be noted firstly that the base 101 is not restricted and it can be a base substrate in an array substrate or a color filter substrate of a liquid crystal display device (abbreviated as LCD), or alternatively, it can be a base substrate or a packaging substrate of an array substrate of an organic light-emitting diode (abbreviated as OLED). Over this, it can be a glass substrate or a flexible base substrate which is not restricted here.

In addition, the base 101 can be a member that is individually used in manufacturing processes for a display device. For example, it can be an upper polarizer or a lower polarizer in a liquid crystal display device, or can be a light guide plate, an optical film, or the like in a backlight module.

It is to be noted secondly that since the attenuation device for blue light 10 attenuates the blue light only by its optical performance other than by completely absorbing the blue light, and since the attenuation device for blue light 10 is applied to a display device which has an image display function, i.e., it is required to ensure a corresponding light transmittance, materials of the film layer of first refractive index 102 and the film layer of second refractive index 103 are light-transmissive material.

In addition, the materials for the film layer of first refractive index 102 and the film layer of second refractive index 103 are required to have properties of mechanical fastness and chemical stability or the like.

It is to be noted thirdly that since at present the display devices are designed to be light and thin according to the market demand, the total thickness of the display device cannot be too thick. Based on this, although it is only defined in the embodiments of the present invention that the total number of the film layer of first refractive index 102 and the film layer of second refractive index 103 is 5 at least while the thicknesses of the film layer of first refractive index 102 and the film layer of second refractive index 103 are not defined, it should be understood by those skilled in the art that a sum of the thicknesses thereof should be within a proper range on the premise that the attenuation film system for blue light is able to achieve attenuation on blue light. In the embodiments of the present disclosure, the sum of the thicknesses of the film layer of first refractive index 102 and the film layer of second refractive index 103 is 2-3 μm.

It is to be noted fourthly that the refractive indexes of the film layer of first refractive index 102 and the film layer of second refractive index 103 are not restricted, as long as the refractive index of the film layer of first refractive index 102 is greater than the refractive index of the film layer of second refractive index 103.

It is to be noted fifthly that unless otherwise specified, the film layer of first refractive index 102 and the film layer of second refractive index 103 in the embodiments of the present disclosure cover the base 101.

At least one embodiment of the present disclosure provides an attenuation device for blue light 10 for a display device. By alternately providing a film layer of first refractive index 102 and a film layer of second refractive index 103 on the base 101, according to the principle of constructive interference and offset interference, the incident angle of the light in the blue light wavelength band can be made equal to the reflection angle, thereby reducing intensity of the blue light passing through the attenuation device for blue light 10. When it is applied to a display device, damage to eyes caused by the blue light from the display device can be reduced.

By way of example, as illustrated in FIG. 5 which is a schematic spectrogram of a liquid crystal display device with 255 display gray scales, the backlight of the liquid crystal display device is a side-type LED (light emitting diode) backlight, which emits light by exciting yellow phosphor by use of blue light. The wavelength band of the emitted blue light has a center wavelength of 440-460 nm.

As illustrated in FIG. 6 which is a transmittance graph of the attenuation device for blue light 10 according to the embodiments of the present disclosure, a range of wavelength band greater than 460 nm is a transmission region, a range of wavelength band less than 460 nm is a cut-off region, and a range of wavelength band less than 440 nm is a complete cut-off region.

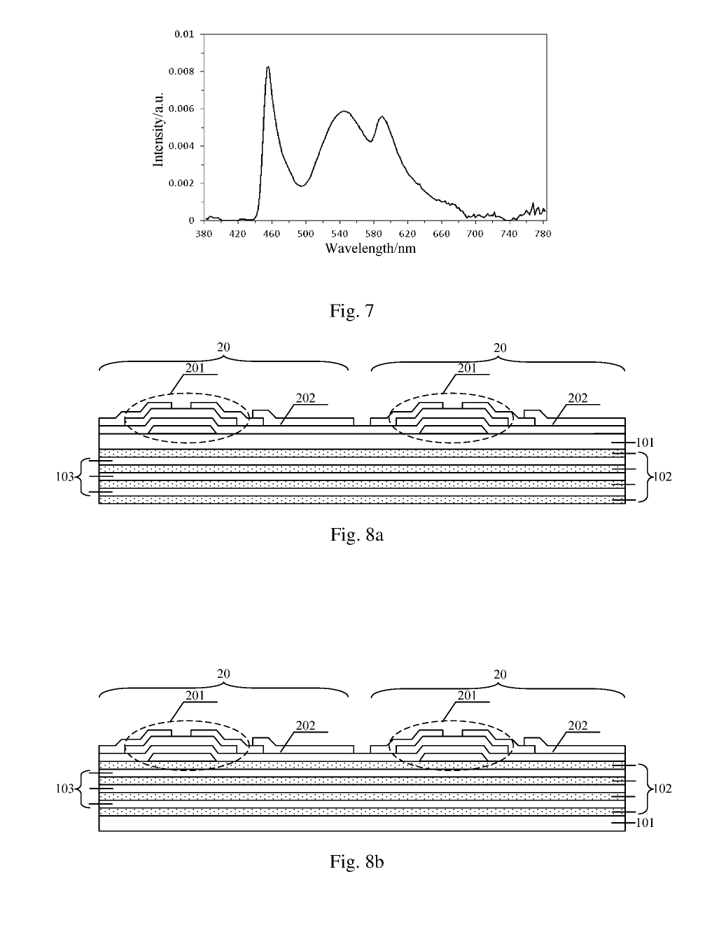

On the basis of this, after attenuating the blue light in FIG. 5 by use of the attenuation device for blue light 10 having the transmittance graph as illustrated in FIG. 6, a schematic spectrogram as illustrated in FIG. 7 can be obtained. It can be seen by making a comparison that, before the attenuation, the intensity of the blue light having a center wavelength of 440-460 nm is close to 0.012 a.u, and after the attenuation, the intensity of the blue light is slightly greater than 0.008 a.u. It can be seen that the intensity of the blue light is significantly attenuated.

It is to be noted that the attenuation degree of blue light and the center wavelength can be obtained by adjusting the thicknesses of the film layer of first refractive index 102 and the film layer of second refractive index 103. Generally speaking, the greater the thickness of the film layer is, the stronger the reflection to the blue light will be and the weaker the transmission of the blue light will be and the better the blue light attenuation effect will be. Of course, the refractive index of the film layer of first refractive index 102 and the refractive index of the film layer of second refractive index 103 can be adjusted. The greater the difference between the refractive index of the film layer of first refractive index 102 and the refractive index of the film layer of second refractive index 103 is, the better the attenuation effect will be.

In one embodiment of the present disclosure, the thickness of each of the film layer of first refractive index 102 and the film layer of second refractive index 103 is between 70 nm and 150 nm.

Thus, even if the total number of the film layer of first refractive index 102 and the film layer of second refractive index 103 amounts to hundreds, the sum of the thicknesses of the film layers of first refractive index 102 and the film layers of second refractive index 103 is only in the order of microns, which has an almost negligible influence on the thickness of the display device.

In consideration of preparation complexity and process feasibility in case that the attenuation device for blue light 10 is applied to a display device, in practice, the total number of the film layers of first refractive index 102 and the film layers of second refractive index 103 is 21 at most in the embodiments of the present disclosure.

In accordance with the above, in one embodiment of the present disclosure, materials for the film layer of first refractive index 102 comprise at least one of silicon nitride, titanium dioxide and zirconium dioxide. Materials for the film layer of second refractive index 103 comprise at least one of silicon dioxide, magnesium fluoride, hafnium oxide and alumina.

The processes for preparing a conventional display device without the attenuation device for blue light 10 comprises processes of forming a silicon nitride film layer and a silicon oxide film layer (mainly used as an insulation layer). Therefore, in one embodiment of the present disclosure, material for the film layer of first refractive index 102 is silicon nitride (having a refractive index in the range of 1.7-3.0) and material for the film layer of second refractive index 103 is silicon dioxide (typically having a refractive index of 1.48). Thus, the existing apparatus can be used, while no new apparatus is required. Further, since the cost of silicon nitride and silicon dioxide is relatively low, the attenuation device for blue light 10 can be produced at a low cost, without significantly increasing the cost of the display device.

It is to be noted that the refractive index of the film layer of first refractive index 102 made of the silicon nitride material is inversely proportional to the nitrogen content. Therefore, the nitrogen content of the film layer of first refractive index 102 can be set as required.

At least one embodiment of the present disclosure further provides a substrate for a display device. The substrate comprises the above-described attenuation device for blue light 10 which is used to attenuate the intensity of the incident blue light.

The substrate can be an array substrate or a color filter substrate of an LCD, or can be an array substrate or a packaging substrate of an OLED. Over this, the attenuation device for blue light 10 is disposed in such a position that it can receive the light incident therein and thereby attenuating the intensity of blue light.

At least one embodiment of the present disclosure provides a substrate comprising the attenuation device for blue light 10. By alternately providing the film layer of first refractive index 102 and a film layer of second refractive index 103 on the base 101, according to the principle of constructive interference and offset interference, the incident angle of the light in the blue light wavelength band can be made equal to the reflection angle, thereby reducing the intensity of the blue light passing through the attenuation device for blue light 10. When it is applied to a display device, damage caused by the blue light from the display device can be reduced.

In one embodiment of the present disclosure, as illustrated in FIGS. 8-11, the substrate further comprises a display element 20. The display element 20 and the attenuation film system for blue light are provided on the same side of the base 101. Alternatively, the display element 20 and the attenuation film system for blue light are provided on opposite sides of the base 101, respectively. The attenuation film system for blue light is inseparable as a whole. The base 101 is a base substrate of the substrate. It can be a glass substrate or a flexible base substrate.

It is to be noted that the display element 20 as described in the embodiments of the present disclosure mainly plays a role of achieving the display function. That is, according to the type of the substrate, for a minimum display unit of the corresponding substrate, a structure to achieve the corresponding display function and composed of the patterns of the respective layers is indispensible. The substrate comprises a plurality of display elements.

For example, as illustrated in FIG. 8a and FIG. 8b, when the substrate is an array substrate of an LCD, as for a minimum display unit of the array substrate, the display element 20 comprises a thin film transistor 201 and a pixel electrode 202. The thin film transistor comprises a gate, a gate insulation layer, a semiconductor active layer, a source, and a drain which is electrically connected with the pixel electrode 202.

It is to be noted firstly that the thin film transistor 201 can be an amorphous silicon type thin film transistor, a low temperature polysilicon type thin film transistor, an oxide type thin film transistor, or an organic type thin film transistor. In addition, the thin film transistor can be a top gate type or a bottom gate type. The embodiments of the present disclosure are not limited thereto.

It is to be noted secondly that the source and the drain of the thin film transistor 201 used in all the embodiments of the present disclosure are symmetrical, so there is no difference between the source and the drain. Over this, to distinguish the two electrodes other than the gate of the thin film transistor 201, one of the two electrodes is referred to as the source, and the other is referred to as the drain.

Further, as illustrated in FIG. 8c, the display element 20 can further comprise a common electrode 203.

The Advanced Super Dimensional Switching (abbreviated as ADS) technology can be used to improve the image quality of the product, with advantages of high resolution, high transmittance, low power consumption, wide viewing angle, high aperture ratio, low aberration, no Push Mura and the like. Therefore, in one embodiment of the present disclosure, as illustrated in FIG. 8c, the pixel electrode 202 and the common electrode 203 are disposed in different layers, and relative to the base 101, the upper electrode such as the common electrode 203 is a slit electrode and the lower electrode such as the pixel electrode 202 is a plate electrode.

Of course, in addition to the above, the display element 20 can further comprise some necessary pattern layers such as a protective layer or the like, or some pattern layers for improving display effects or overcoming certain defects.

In addition, the array substrate further comprises a gate line for supplying a signal to the gate of the thin film transistor and a data line for supplying a signal to the source, besides the display element 20 within the minimum display unit of the array substrate.

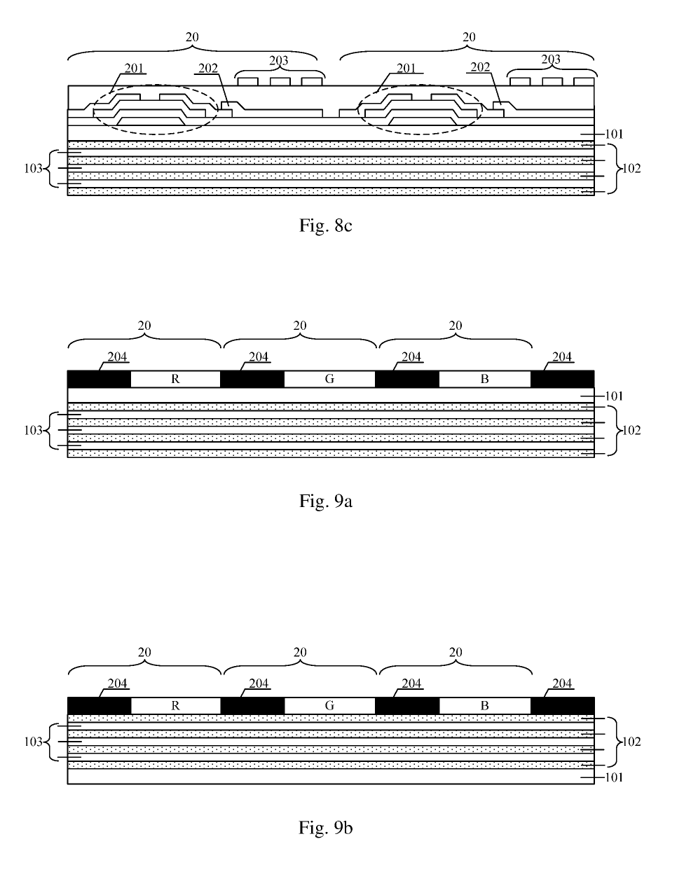

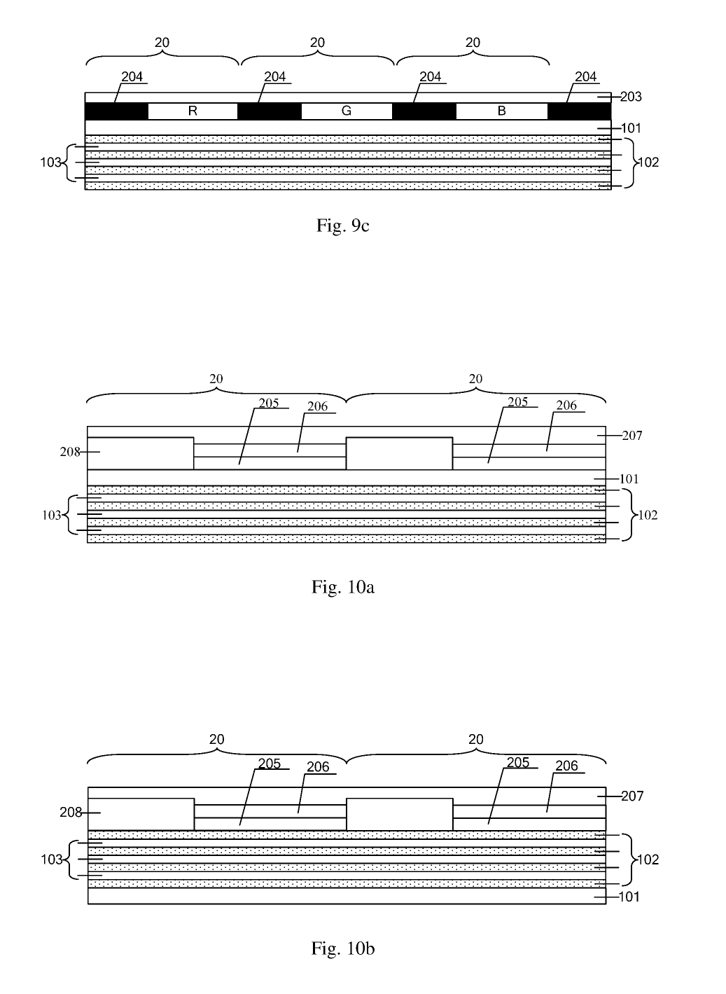

As illustrated in FIG. 9a and FIG. 9b, when the substrate is a color filter substrate of an LCD, as for a minimum display unit of the array substrate, the display element 20 comprises a color filter layer and a black matrix 204; the color filter layer comprises a red color filter R, a green color filter G and a blue color filter B. When the display element 20 of the above-described array substrate does not comprise a common electrode 203, as illustrated in FIG. 9c, the display element 20 on the color filter substrate further comprises a common electrode 203.

Of course, in addition to the above, the display element 20 can further comprise some necessary pattern layers such as a protective layer or the like, or some pattern layers for improving display effects or overcoming certain defects.

Based on the above, to make it unnecessary to take the influence of the processes on the attenuation film system for blue light account during preparation of the display element 20, in one embodiment of the present disclosure, the attenuation film system for blue light and the display element 20 are disposed on opposite sides of the base 101 respectively. That is, when the array substrate or the color filter substrate described above is applied to the LCD, the attenuation film system for blue light is disposed between the array substrate and the lower polarizer or between the color filter substrate and the upper polarizer.

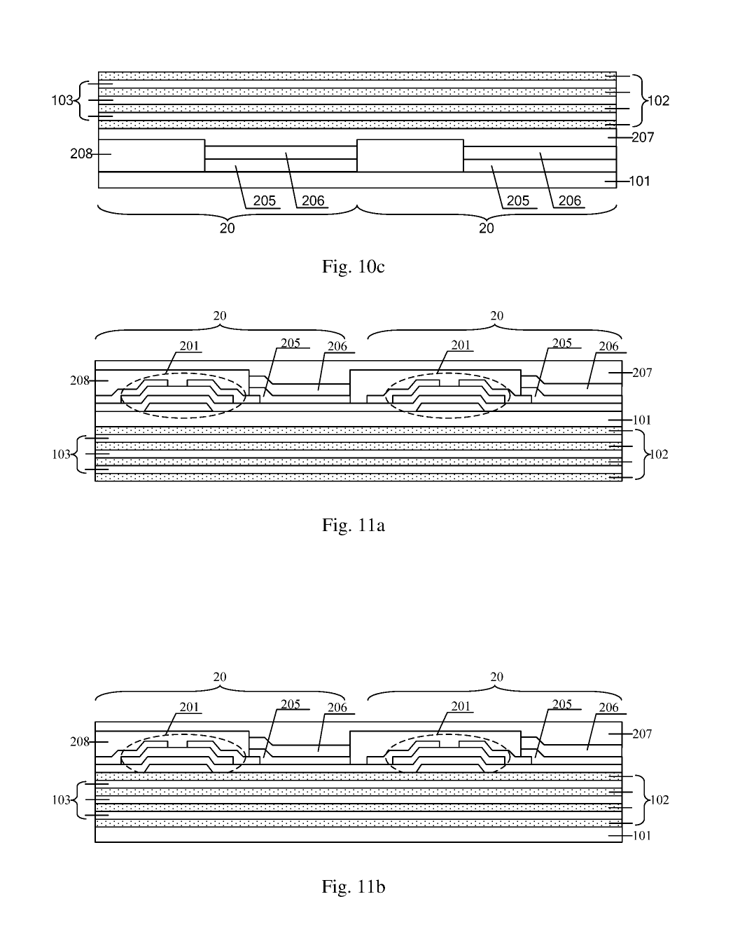

As illustrated in FIG. 10a, FIG. 10b and FIG. 10c, when the substrate is an array substrate of an OLED, as for a minimum display unit of the array substrate, the display element 20 comprises an anode 205, an organic material functional layer 206 and a cathode 207. The attenuation film system for blue light is provided at the light emitting side of the display element 20.

Further, as illustrated in FIG. 11a, FIG. 11b and FIG. 11c, the display element 20 further comprises a thin film transistor 201 and an anode 205 which is electrically connected with the drain of the thin film transistor 201.

Of course, in addition to the above, the display element 20 can further comprise some necessary pattern layers such as a pixel definition layer 208, a protective layer or the like, or some pattern layers for improving display effects or overcoming certain defects.

The organic material functional layer 206 can at least comprise a light emitting layer. Over this, in order to improve the efficiency of electrons and holes injected into the light emitting layer, the organic material functional layer 206 can further comprise an electron transport layer and a hole transport layer. It can further comprise an electron injection layer provided between the cathode 207 and the electron transport layer and a hole injection layer provided between the hole transport layer and the anode 205.

When the cathode 207 is opaque and the anode 205 is transparent, since the light emitted from the organic material functional layer 206 only exits from the anode 205 side, as illustrated in FIGS. 10a and 10b and FIGS. 11a and 11b, the attenuation film system for blue light is provided adjacent to the base 101.

When the cathode 207 is semitransparent and the anode 205 is opaque, since the light emitted from the organic material functional layer 206 only exits from the cathode 207 side, as illustrated in FIG. 10c and FIG. 11c, the blue light attenuating film system is provided above the cathode 207.

When the cathode 207 is semitransparent and the anode 205 is transparent, the attenuation film system for blue light can be provided on each of the light emitting sides. Detailed description of such a structure is omitted here.

It should be noted that when the cathode 207 is semitransparent, it has a relatively small thickness and is made of metallic material. When the anode 205 is opaque, it can have a structure of transparent conductive layer/metal layer/transparent conductive layer.

At least one embodiment of the present disclosure further provides a display device comprising the substrate as described above.

The display device according to the embodiments of the present disclosure can be a product or a component having a display function such as a liquid crystal display device, a liquid crystal television, an OLED display device, an OLED television, a digital photo frame, a cell phone, a tablet computer or the like.

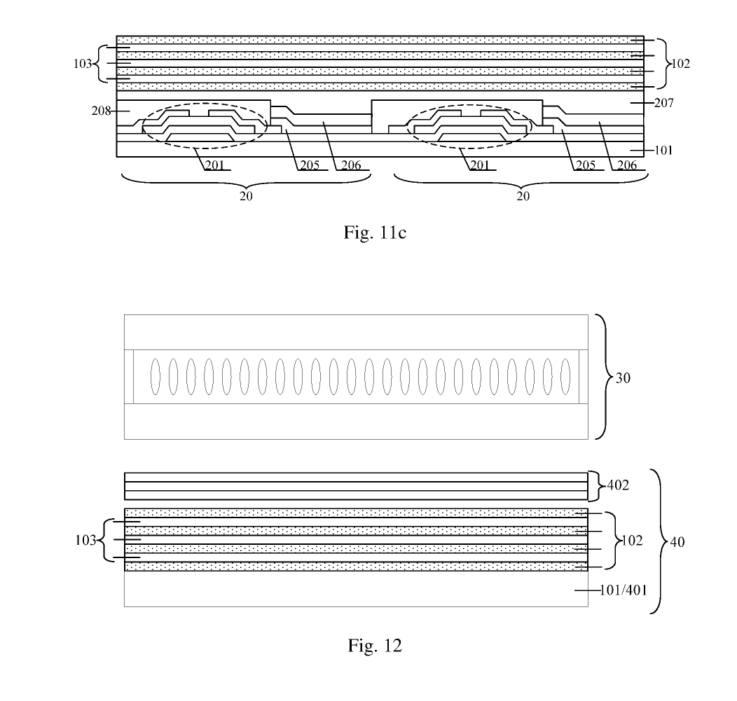

At least one embodiment of the present disclosure further provides a display device of another type. As illustrated in FIG. 12, the display device comprises a liquid crystal display panel 30 and a backlight module 40. The backlight module 40 comprises an attenuation device for blue light 10. The base 101 of the attenuation device for blue light 10 is a light guide plate 401 or an optical film 402.

In addition, the backlight module 40 further comprises a light source (not shown in the drawings) which can be provided under the base 101 or can be provided at a side face of the base 101.

It should be noted that if the display device is of the slim and thin type, the optical film 402 can comprise a lower diffusion sheet, a lower prism film, an upper prism film or the like. If the display device is not of the slim and thin type, the optical film 402 can further comprise an upper diffusion sheet.

In addition, the light guide plate 401, the optical film 402 and the light source can be secured by a back plate and a plastic frame, which are not restricted by the present disclosure.

At least one embodiment of the present disclosure further provides a smart wearable product comprising the above-described display device.

The smart wearable product according to the embodiments of the present disclosure can be a smart wearable apparatus such as a smart watch, a smart bracelet or the like.

At least one embodiment of the present disclosure further provides a preparation method of the above-described attenuation device for blue light 10. Referring to FIG. 1 to FIG. 3, the method comprises evaporating by evaporation method or depositing by chemical vapor deposition method the film layer of first refractive index 102 and the film layer of second refractive index 103 sequentially on the same side of the base 101. A total number of the film layer of first refractive index 102 and the film layer of second refractive index 103 is 5 at least. The film layer of first refractive index 102 has a refractive index greater than that of the film layer of second refractive index 103. The first layer and the last layer are both the film layer of first refractive index 102.

Here, if the evaporation method is used, the film layer of first refractive index 102 and the film layer of second refractive index 103 are both formed by using the evaporation method. If the chemical vapor deposition method is used, the film layer of first refractive index 102 and the film layer of second refractive index 103 are both formed by using the chemical vapor deposition method. Therefore, it is not necessary to change the apparatus during the preparation process which otherwise would make the process complex.

At least one embodiment of the present disclosure provides a preparation method of an attenuation device for blue light 10. By alternately providing a film layer of first refractive index 102 and a film layer of second refractive index 103 on the base 101, according to the principle of constructive interference and offset interference, the incident angle of the light in the blue light wavelength band can be made equal to the reflection angle, thereby reducing the intensity of the blue light passing through the attenuation device for blue light 10. When it is applied to a display device, damage caused by the blue light in the display device can be reduced.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510596020.4 filed on Sep. 17, 2015, the disclosure of which is hereby entirely incorporated by reference as a part of the present disclosure.

1. An attenuation device for blue light applicable to a display device, comprising a base and a blue light attenuating film system, the blue light attenuating film system comprising a film layer of first refractive index and a film layer of second refractive index alternately disposed on the same side of the base, a total number of the film layer of first refractive index and the film layer of second refractive index being 5 at least;
a film layer closest to the base and a film layer farthest from the base in the blue light attenuating film system are both the film layer of first refractive index, and the film layer of first refractive index has a refractive index greater than that of the film layer of second refractive index.

2. The attenuation device for blue light according to claim 1, wherein each of the film layer of first refractive index and the film layer of second refractive index has a thickness in a range of 70-150 nm.

3. The attenuation device for blue light according to claim 1, wherein the total number of the film layer of first refractive index and the film layer of second refractive index is 21 at most.

4. The attenuation device for blue light according to claim 1, wherein the film layer of first refractive index is made of at least one of silicon nitride, titanium dioxide and zirconium dioxide; and
the film layer of second refractive index is made of at least one of silicon dioxide, magnesium fluoride, hafnium oxide and alumina.

5. A substrate applicable to a display device, comprising the attenuation device for blue light according to claim 1, wherein the attenuation device for blue light is configured to attenuate intensity of blue light incident therein.

6. The substrate according to claim 5, wherein the substrate further comprises a display element;
the display element and the blue light attenuation film system are provided on the same side of the base; or
the display element and the blue light attenuation film system are provided on opposite sides of the base, respectively.

7. The substrate according to claim 6, wherein the display element comprises a thin film transistor and a pixel electrode electrically connected with a drain of the thin film transistor.

8. The substrate according to claim 6, wherein the display element comprises a color film layer and a black matrix.

9. The substrate according to claim 6, wherein the display element comprises an anode, an organic material functional layer and a cathode, wherein the blue light attenuating film system is provided on a light emitting side of the display element.

10. A display device, comprising the substrate as claimed in claim 5.

11. A display device, comprising a liquid crystal display panel and a backlight source, wherein the backlight source comprises the attenuation device for blue light as claimed in claim 1, and wherein the base of the attenuation device for blue light is a light guide plate or an optical film.

12. A smart wearable product, comprising the display device as claimed in claim 10.

13. A preparation method of the attenuation device for blue light as claimed in claim 1, comprising:
evaporating by evaporation method or depositing by chemical vapor deposition method the film layer of first refractive index and the film layer of second refractive index sequentially on the same side of the base, a total number of the film layer of first refractive index and the film layer of second refractive index is 5 at least;
a film layer closest to the base and a film layer farthest from the base are both the film layer of first refractive index, and the film layer of first refractive index has a refractive index greater than that of the film layer of second refractive index.

14. The attenuation device for blue light according to claim 2, wherein the total number of the film layer of first refractive index and the film layer of second refractive index is 21 at most.

15. The attenuation device for blue light according to claim 2, wherein the film layer of first refractive index is made of at least one of silicon nitride, titanium dioxide and zirconium dioxide; and
the film layer of second refractive index is made of at least one of silicon dioxide, magnesium fluoride, hafnium oxide and alumina.

16. The attenuation device for blue light according to claim 3, wherein the film layer of first refractive index is made of at least one of silicon nitride, titanium dioxide and zirconium dioxide; and
the film layer of second refractive index is made of at least one of silicon dioxide, magnesium fluoride, hafnium oxide and alumina.

17. A substrate applicable to a display device, comprising the attenuation device for blue light according to claim 2, wherein the attenuation device for blue light is configured to attenuate intensity of blue light incident therein.

18. A substrate applicable to a display device, comprising the attenuation device for blue light according to claim 3, wherein the attenuation device for blue light is configured to attenuate intensity of blue light incident therein.

19. A substrate applicable to a display device, comprising the attenuation device for blue light according to claim 4, wherein the attenuation device for blue light is configured to attenuate intensity of blue light incident therein.

20. The substrate according to claim 17, wherein the substrate further comprises a display element;
the display element and the blue light attenuation film system are provided on the same side of the base; or
the display element and the blue light attenuation film system are provided on opposite sides of the base, respectively.
